(19) United States
(12) Patent Application Publication
(10) Pub. No.: US 2009/0202938 A1
(43) Pub. Date: Aug. 13, 2009

(54) METHOD OF IMPROVING SURFACE ABRASION RESISTANCE OF IMAGEABLE ELEMENTS

(76) Inventors: Celin Savariar-Hauck, Badenhausen (DE); Marco Scala, Hatterheim (DE); Mirko Hartleb, Katlenburg-Lindau (DE)

Correspondence Address: EASTMAN KODAK COMPANY;PATENT LEGAL STAFF, 343 STATE STREET, ROCHESTER, NY, 14650-2201, US

(21) Appl. No.: 12/028,063

(22) Filed: Feb. 8, 2008

(51) Int. Cl. G03F 7/004; G03F 7/12

(52) U.S. Cl. 430/270.1; 430/326

(57) ABSTRACT

A computer-to-press multi-layer, positive-working imageable element has improved surface abrasion resistance from a micro-roughening of the outermost surface. This improvement is provided by spraying a solution consisting essentially of one or more dissolved organic resins in a solvent onto the outermost imageable layer of the imageable element. The one or more organic resins are soluble or dispersible in an aqueous alkaline solution and are present in the sprayed solution in an amount of at least 3 weight %. The sprayed solution is applied to deposit at least 10 mg/m² and no more than 100 mg/m² of the one or more dissolved organic resins onto the outermost imageable layer in the form of dots in a random pattern. The sprayed dots are then dried. The imageable elements can be imaged and developed to provide lithographic printing plates.

### FIELD OF THE INVENTION

This invention provides positive-working imageable elements with improved scratch abrasion resistance for its outermost imaging surface. This invention also includes a method for providing this improved scratch abrasion resistance.

### BACKGROUND OF THE INVENTION

In conventional or “wet” lithographic printing, ink receptive regions, known as image areas, are generated on a hydrophilic surface. When the surface is moistened with water and ink is applied, the hydrophilic regions retain the water and repel the ink, and the ink receptive regions accept the ink and repel the water. The ink is transferred to the surface of a material upon which the image is to be reproduced. For example, the ink can be first transferred to an intermediate blanket that in turn is used to transfer the ink to the surface of the material upon which the image is to be reproduced.

Imageable elements useful to prepare lithographic printing plates typically comprise an imageable layer applied over the hydrophilic surface of a substrate. The imageable layer includes one or more radiation-sensitive components that can be dispersed in a suitable binder. Alternatively, the radiation-sensitive component can also be the binder material. Following imaging, either the imaged regions or the non-imaged regions of the imageable layer are removed by a suitable developer, revealing the underlying hydrophilic surface of the substrate. If the imaged regions are removed, the element is considered as positive-working. Conversely, if the non-imaged regions are removed, the element is considered as negative-working. In each instance, the regions of the imageable layer (that is, the image areas) that remain are ink-receptive, and the regions of the hydrophilic surface revealed by the developing process accept water and aqueous solutions, typically a fountain solution, and repel ink.

Direct digital imaging has become increasingly important in the printing industry. Imageable elements for the preparation of lithographic printing plates have been developed for use with infrared lasers. Thermally imageable, multi-layer elements are described, for example, in U.S. Pat. No. 6,294,311 (Shimazu et al.), U.S. Pat. No. 6,352,812 (Shimazu et al.), U.S. Pat. No. 6,593,055 (Shimazu et al.), U.S. Pat No. 6,352,811 (Patel et al.), and U.S. Pat. No. 6,528,228 (Savariar-Hauck et al.), and U.S. Patent Application Publication 2004/0067432 A1 (Kitson et al.). U.S. Patent Application Publication 2005/0037280 (Loccufier et al.) describes heat-sensitive printing plate precursors that comprise a phenolic developer-soluble polymer and an infrared radiation absorbing agent in the same layer.

Additional positive-working thermally imageable elements are described and used for making lithographic printing plates using various developers in U.S. Pat. No. 6,200,727 (Urano et al.), U.S. Pat. No. 6,358,669 (Savariar-Hauck et al), and U.S. Pat. No. 6,534,238 (Savariar-Hauck et al.). In some instances, such imageable elements are developed using low pH developers when the upper layer includes novolak resins and dissolution suppressing agents.

Single-layer, positive-working imageable elements are described for example, in U.S. Pat. No. 6,280,899 (Hoare et al.), U.S. Pat. No. 6,391,524 (Yates et al.), U.S. Pat. No. 6,485,890 (Hoare et al.), U.S. Pat. No. 6,558,869 (Hearson et al.), and U.S. Pat. No. 6,706,466 (Parsons et al.), and U.S. Patent Application Publication 2006/0130689 (Müller et al.).

Copending and commonly assigned, U.S. Ser. No. 11/686,981 (filed Mar. 16, 2006 by Savariar-Hauck et al.) describes and claims a method of processing positive-working imageable elements to prepare lithographic printing plates. Other imageable elements are described in U.S. Pat. No. 6,555,291 (Savariar-Hauck).

Particulate materials have been incorporated into lithographic printing plate precursors for various reasons. For example, organic polymer particles have been incorporated into such elements for improved press developability as described in U.S. Pat. No. 6,352,811 (Patel et al.). Nanopastes of metallic particles are described for imageable elements in U.S. Pat. No. 7,217,502 (Ray et al.). Core-shell particles have been included in imaging layers so they coalesce upon imaging as described for example in EP 1,057,622 (Fukino et al.).

Improving the abrasion resistance of the outer surface of imageable elements such as lithographic printing plate precursors has been the focus of the industry for some time. This has been a particular concern with certain positive-working imageable elements that are composed of outer layer compositions that are easily scratched during handling, imaging, or development.

An advance in abrasion resistance was recently achieved by incorporating nano-scale inorganic particles into the outermost imageable layer, as described in copending and commonly assigned U.S. Ser. No. 11/847,368 filed Aug. 30, 2007 by Gerhard Hauck and Celin Savariar-Hauck.

Sprays containing solid matte agents are applied to photosensitive elements in U.S. Pat. No. 6,500,494 (Hauck et al.), which photosensitive elements are imaged through a mask. Digital elements are specifically excluded from this process. GB 1,495,361 (Fuji Photo) also describes the application of a matt layer onto similar light-sensitive printing plates.

Sprayed resin droplets are applied to outermost layers in elements to improve vacuum drawdown in U.S. Pat. No. 5,948,595 (Watanabe).

Granular matting agents are applied to IR-sensitive lithographic printing plate precursors in EP 1,806,620A1 (Miyamoto et al.). The matting agent includes an IR-absorbing dye. A pattern of novolac resin can be applied using an ink jet printer according to EP 1,046,497A1 (Oelbrandt et al.).

### Problem to be Solved

Despite the various attempts described in the art, there remains a need to improve the surface abrasion resistance of computer-to-press positive-working, multi-layer imageable elements using simple procedures. Some of the known positive-working imageable elements are susceptible to surface scratches or other damage from routine handling.

### SUMMARY OF THE INVENTION

To address the abrasion resistance problem, a method of micro-roughening a computer-to-press multi-layer, positive-working imageable element comprises:

spraying a solution consisting essentially of one or more dissolved organic resins in a solvent onto the outermost imageable layer of a computer-to-press multi-layer, positive-working imageable element, the one or more organic resins being soluble or dispersible in an aqueous alkaline solution and being present in the solution in an amount of at least 3 weight %, the sprayed solution being applied in a manner to deposit at least 10 mg/m² and no more than 100 mg/m² of the one or more dissolved organic resins onto the outermost imageable layer in the form of dots in a random pattern, and

drying the sprayed dots.

This invention also provides a method of preparing a computer-to-press multi-layer, positive-working imageable element comprising:

A) providing a computer-to-press multi-layer, positive-working imageable element comprising a substrate having thereon one or more imageable layers,

B) spraying a solution consisting essentially of one or more dissolved organic resins in a solvent onto the outermost imageable layer of the element, the one or more organic resins being soluble or dispersible in an aqueous alkaline solution and being present in the solution in an amount of at least 3 weight %, the sprayed solution being applied in a manner to deposit at least 10 mg/m² and no more than 100 mg/m² of the one or more dissolved organic resins onto the outermost imageable layer in the form of dots in a random pattern, and

C) drying the dots on the outermost imageable layer to provide a random pattern of dried dots of the one or more organic resins.

For example, the invention provides a computer-to-press positive-working imageable element comprising a substrate and having thereon at least two imageable layers, one of which is the outermost layer of the imageable element,

the outermost element having disposed thereon dots in a random pattern, the dots consisting essentially of one or more one or more organic resins that are soluble or dispersible in an aqueous alkaline solution.

Still again, a method for providing a an imaged element comprises:

A) imaging the computer-to-press multi-layer, positive-working imageable element of this invention to provide both exposed regions and non-exposed regions in an imaged element, and

B) developing the imaged element to remove only the exposed regions.

The present invention provides multi-layer positive-working imageable elements having improved abrasion resistance because of micro-roughening the outermost surface by spraying organic resins to provide random dots on that surface. The increased abrasion resistance reduces the possibility of scratches and other physical defects in the outermost layer so there are reduced defects in the resulting images. With increase scratch resistance, the imageable elements are more handleable during manufacture, stacking, interleaving, packaging, transport, auto-loading, and use.

Thus, the imageable elements are more readily handled during manufacturing, sheeting, stacking, interleaving, packaging, transport, and pre-press auto-loading, imaging, and development. The presence of the dots on the outer surface can also reduce stickiness when the imageable elements are stacked with interleaving papers during storage or transport. This invention is particularly useful for improving the abrasion resistance of “computer-to-press” multi-layer positive-working lithographic printing plate precursors.

### DETAILED DESCRIPTION OF THE INVENTION

### Definitions

Unless the context indicates otherwise, when used herein, the terms “imageable element”, “positive-working imageable element”, and “printing plate precursor” are meant to be references to embodiments of the present invention.

In addition, unless the context indicates otherwise, the various components described herein such as “primary polymeric binder”, “secondary polymeric binder”, “dissolution inhibitor”, “radiation absorbing compound”, and similar terms also refer to mixtures of such components. Thus, the use of the article “a” or “an” is not necessarily meant to refer to only a single component.

By “multi-layer” imageable element, we mean an imageable element of this invention that has at least two layers required for providing an image, for example, “inner” and “outer” layers as described below. However, such elements may comprise additional non-imaging layers on either side of the substrate.

By the term “remove said exposed regions” during development, we mean that the exposed regions of the outermost layer and the corresponding regions of any underlying layers are selectively and preferentially removed by the developer, but not the non-exposed regions.

By “computer-to-press”, we mean that imaging is carried out using a computer-directed imaging means (such as a laser) directed to the imageable layers without using masking or other intermediate imaging films.

Unless otherwise indicated, percentages refer to percents by dry weight, based on either the dry solids of a composition or formulation, or the dry coated weight of a layer. Thus, the percentages stated for formulations or compositions will likely be the same as those for the dry coated layers.

For clarification of definitions for any terms relating to polymers, reference should be made to “Glossary of Basic Terms in Polymer Science” as published by the International Union of Pure and Applied Chemistry (“IUPAC”), Pure Appl. Chem. 68, 2287-2311 (1996). However, any definitions explicitly set forth herein should be regarded as controlling.

Unless otherwise indicated, the term “polymer” refers to high and low molecular weight polymers including oligomers and includes homopolymers and copolymers.

The term “copolymer” refers to polymers that are derived from two or more different monomers. That is, they comprise recurring units having at least two different chemical structures.

The term “backbone” refers to the chain of atoms in a polymer to which a plurality of pendant groups can be attached. An example of such a backbone is an “all carbon” backbone obtained from the polymerization of one or more ethylenically unsaturated polymerizable monomers. However, other backbones can include heteroatoms wherein the polymer is formed by a condensation reaction or some other means.

### Uses

The imageable elements described herein can be used in a number of ways such as precursors to lithographic printing plates as described in more detail below. However, this is not meant to be their only use. For example, the imageable elements can also be used as thermal patterning systems and to form masking elements and printed circuit boards.

### Spray Solutions for Abrasion Resistance

The micro-roughening procedure useful to provide the advantage of improved abrasion resistance it achieved by spraying a solution consisting essentially of one or more dissolved organic resins in a solvent onto the outermost imageable layer of a computer-to-press multi-layer positive-working imageable element (defined below). The spraying operation can be carried out in any suitable manner, typically using high pressure, to provide a random pattern of “dots” or sprayed droplets of the noted solution. For example, the solution can be sprayed using high-pressure nozzles or by electrostatic spraying. High-pressure nozzles are readily available from various commercial sources and can be fitted into a high-pressure system that is used to deliver the solution in fine droplet form to the outer surface of the imageable element. Electrostatic spraying is also known in the art and uses the imageable element as an anode and a solution spraying device as the cathode. An electrostatic field is created between the anode and cathode by applying high negative voltage and negatively charging the solution to be sprayed.

The sprayed droplets may be so fine as to almost be dried by the time they contact the surface of the imageable element. If further drying is needed, it can be provided with hot air or infrared dryers. The resulting dried dots on the surface can have a diameter of from about 0.5 to about 300 μm and more likely from about 5 to about 50 μm. The sprayed solution is applied in a manner to deposit at least 10 mg/m² and no more than 100 mg/m² of the one or more dissolved organic resins onto the surface of the outermost imageable layer in the form of dots in a random pattern. Typically, from about 20 to about 50 mg/m² of the organic resins are deposited on the surface.

The one or more organic resins in the sprayed solution can be any polymeric material that is soluble or dispersible in an aqueous alkaline solution so it can be removed during development. The organic resins are generally present in the solution in an amount of at least 3 weight %, and typically from about 3 to about 20 weight %. Useful organic resins include but are not limited to, novolaks, resoles, polyhydroxystyrenes, (meth)acrylic acid copolymers, poly(vinyl acetal)s, cellulose ester derivatives, cyclic anhydride copolymers, polyurethanes, and polymeric sulfonamide derivatives. Details and examples of such polymers are either described below in relation to binders of the imageable layers, or they are readily known to one skilled in the art and could be purchased from a number of commercial sources. In many embodiments, the organic resins used in the sprayed solutions include one or more novolak resins.

The sprayed solution has no components that render it sensitive to infrared radiation. Moreover, the dried dots applied to the outermost surface of the imageable elements are “inert” meaning that they do not have appreciable surface reactivity (surface reactive groups). Thus, the components in the dots do not react with the surrounding polymeric binder or other components of the imageable layer to any appreciable extent. Such reactivity is not needed for providing the desired abrasion resistance.

The sprayed solution can include one or more anionic, cationic, or nonionic surfactants to help disperse the organic resins in the solution solvents. The particular surfactants used can be adjusted to be compatible with the dispersed or dissolved organic resins and this would require only routine experimentation.

The solvents into which the organic resins are dispersed or dissolved can be readily chosen depending upon the organic resins to be used and the apparatus used to spray the solution. Useful solvents include but are not limited to, isobutylacetate, isopropanol, propylene glycol, methyl ethyl acetate, and ethanol, and mixtures thereof.

Examples of useful sprayed solutions containing organic resins are illustrated in the Invention Examples below.

### Multi-layer Positive-Working Imageable Elements

In general, the multi-layer imageable elements comprise a substrate, an inner layer (also known in the art as an “underlayer”), and an outer layer (also known in the art as a “top layer” or “topcoat”) disposed over the inner layer. Before thermal imaging, the outer layer is generally not soluble or removable by an alkaline developer within the usual time allotted for development, but after thermal imaging, the exposed regions of the outer layer are soluble in the alkaline developer. The inner layer is also generally removable by the alkaline developer. An infrared radiation absorbing compound (described above) can also be present in such imageable elements, and is typically present in the inner layer but may optionally be in a separate layer between the inner and outer layers.

The imageable elements are formed by suitable application of an inner layer composition onto a suitable substrate. This substrate can be an untreated or uncoated support but it is usually treated or coated in various ways as described above prior to application of the inner layer composition. The substrate generally has a hydrophilic surface or at least a surface that is more hydrophilic than the outer layer composition. The substrate comprises a support that can be composed of any material that is conventionally used to prepare imageable elements such as lithographic printing plates.

The substrate generally has a hydrophilic surface, or at least a surface that is more hydrophilic than the applied imageable layer formulation on the imaging side. The substrate comprises a support that can be composed of any material that is conventionally used to prepare imageable elements such as lithographic printing plates. It is usually in the form of a sheet, film, or foil, and is strong, stable, and flexible and resistant to dimensional change under conditions of use so that color records will register a full-color image. Typically, the support can be any self-supporting material including polymeric films (such as polyester, polyethylene, polycarbonate, cellulose ester polymer, and polystyrene films), glass, ceramics, metal sheets or foils, or stiff papers (including resin-coated and metallized papers), or a lamination of any of these materials (such as a lamination of an aluminum foil onto a polyester film). Metal supports include sheets or foils of aluminum, copper, zinc, titanium, and alloys thereof.

Polymeric film supports may be modified on one or both surfaces with a “subbing” layer to enhance hydrophilicity, or paper supports may be similarly coated to enhance planarity. Examples of subbing layer materials include but are not limited to, alkoxysilanes, amino-propyltriethoxysilanes, glycidioxypropyl-triethoxysilanes, and epoxy functional polymers, as well as conventional hydrophilic subbing materials used in silver halide photographic films (such as gelatin and other naturally occurring and synthetic hydrophilic colloids and vinyl polymers including vinylidene chloride copolymers).

A useful substrate is composed of an aluminum-containing support that may be coated or treated using techniques known in the art, including physical graining, electrochemical graining, chemical graining, and anodizing. For example, the aluminum sheet can be anodized using phosphonic acid or sulfuric acid using conventional procedures.

An optional interlayer may be formed by treatment of the aluminum support with, for example, a silicate, dextrine, calcium zirconium fluoride, hexafluorosilicic acid, phosphate/fluoride, poly(vinyl phosphonic acid) (PVPA), vinyl phosphonic acid-acrylic acid copolymer, poly(acrylic acid), or (meth)acrylic acid copolymer, or mixtures thereof. For example, the grained and/or anodized aluminum support can be treated with poly(phosphonic acid) using known procedures to improve surface hydrophilicity to provide a lithographic hydrophilic substrate.

The thickness of the substrate can be varied but should be sufficient to sustain the wear from printing and thin enough to wrap around a printing form. Such embodiments typically include a treated aluminum foil having a thickness of from about 100 to about 600 μm.

The backside (non-imaging side) of the substrate may be coated with antistatic agents and/or slipping layers or a matte layer to improve handling and “feel” of the imageable element.

The substrate can also be a cylindrical surface having the radiation-sensitive composition applied thereon, and thus be an integral part of the printing press or a sleeve that is incorporated onto a press cylinder. The use of such imaged cylinders is described for example in U.S. Pat. No. 5,713,287 (Gelbart).

The inner layer is disposed between the outer layer and the substrate. Typically, it is disposed directly on the substrate (including any hydrophilic coatings as described above). The inner layer comprises a first polymeric binder that is removable by the lower pH developer and typically soluble in the developer to reduce sludging of the developer. In addition, the first polymeric binder is usually insoluble in the solvent used to coat the outer layer so that the outer layer can be coated over the inner layer without dissolving the inner layer. Mixtures of these first polymeric binders can be used if desired in the inner layer.

Useful first polymeric binders for the inner layer include (meth)acrylonitrile polymers, (meth)acrylic resins comprising carboxy groups, polyvinyl acetals, maleated wood rosins, styrene-maleic anhydride copolymers, (meth)acrylamide polymers including polymers derived from N-alkoxyalkyl methacrylamide, polymers derived from an N-substituted cyclic imide, polymers having pendant cyclic urea groups, and combinations thereof First polymeric binders that provide resistance both to fountain solution and aggressive washes are disclosed in U.S. Pat. No. 6,294,311 (noted above).

Useful first polymeric binders include (meth)acrylonitrile polymers, and polymers derived from an N-substituted cyclic imide (especially N-phenylmaleimide), a (meth)acrylamide (especially methacrylamide), a monomer having a pendant cyclic urea group, and a (meth)acrylic acid (especially methacrylic acid). First polymeric binders of this type include copolymers that comprise from about 20 to about 75 mol % and typically about 35 to about 60 mol % or recurring units derived from N-phenylmaleimide, N-cyclohexyl-maleimide, N-(4-carboxyphenyl)maleimide, N-benzylmaleimide, or a mixture thereof, from about 10 to about 50 mol % and typically from about 15 to about 40 mol % of recurring units derived from acrylamide, methacrylamide, or a mixture thereof, and from about 5 to about 30 mol % and typically about 10 to about 30 mol % of recurring units derived from methacrylic acid. Other hydrophilic monomers, such as hydroxyethyl methacrylate, may be used in place of some or all of the methacrylamide. Other alkaline soluble monomers, such as acrylic acid, may be used in place of some or all of the methacrylic acid. Optionally, these polymers can also include recurring units derived from (meth)acrylonitrile or N-[2-(2-oxo-1-imidazolidinyl)ethyl]-methacrylamide.

The bakeable inner layers described in WO 2005/018934 (Kitson et al.) and U.S. Pat. No. 6,893,783 (Kitson et al.) may also be used.

Other useful first polymeric binders can comprise, in polymerized form, from about 5 mol % to about 30 mol % of recurring units derived from an ethylenically unsaturated polymerizable monomer having a carboxy group (such as acrylic acid, methacrylic acid, itaconic acid, and other similar monomers known in the art (acrylic acid and methacrylic acid are preferred), from about 20 mol % to about 75 mol % of recurring units derived from N-phenylmaleimide, N-cyclohexylmaleimide, or a mixture thereof, optionally, from about 5 mol % to about 50 mol % of recurring units derived from methacrylamide, and from about 3 mol % to about 50 mol % of one or more recurring units derived from monomer compounds of the following Structure:

CH₂═C(R₂)—C(═O)—NH—CH₂—OR₁

wherein R₁ is a C₁ to C₁₂ alkyl, phenyl, C₁ to C₁₂ substituted phenyl, C₁ to C₁₂ aralkyl, or Si(CH₃)₃, and R₂ is hydrogen or methyl. Methods of preparation of certain of these polymeric materials are disclosed in U.S. Pat. No. 6,475,692 (Jarek).

Additional useful polymeric binders for the inner layer are described for example, in U.S. Pat. No. 7,144,661(Ray et al.), U.S. Pat. No. 7,163,777 (Ray et al.), and U.S. Pat. No. 7,223,506 (Kitson et al.), and U.S. Patent Application Publications 2006/0257764 (Ray et al.) and 2007/0172747 (Ray et al.).

Useful primary additional polymeric materials include copolymers that comprises from about 1 to about 30 mole % of recurring units derived from N-phenylmaleimide, from about 1 to about 30 mole % of recurring units derived from methacrylamide, from about 20 to about 75 mole % of recurring units derived from acrylonitrile, and from about 20 to about 75 mole % of recurring units derived from one or more monomers of the Structure (XI):

CH₂═C(R₂₃)—CO₂—CH₂CH₂—NH—CO—NH-p-C₆H₄—R₂₂ (XI)

wherein R₂₂ is OH, COOH, or SO₂NH₂, and R₂₃ is H or methyl, and, optionally, from about 1 to about 30 mole % from about 3 to about 20 mole % of recurring units derived from one or more monomers of the Structure (XII):

CH₂═C(R₂₅)—CO—NH-p-C₆H₄—R₂₄ (XII)

wherein R₂₄ is OH, COOH, or SO₂NH₂, and R₂₅ is H or methyl.

The inner layer may also comprise one or more secondary additional polymeric materials that are resins having activated methylol and/or activated alkylated methylol groups. These “secondary additional polymeric materials” in the inner layer should not be confused with the “second polymeric binder” used in the outer layer.

The secondary additional polymeric materials can include, for example resole resins and their alkylated analogs, methylol melamine resins and their alkylated analogs (for example melamine-formaldehyde resins), methylol glycoluril resins and alkylated analogs (for example, glycoluril-formaldehyde resins), thiourea-formaldehyde resins, guanamine-formaldehyde resins, and benzoguanamine-formaldehyde resins. Commercially available melamine-formaldehyde resins and glycoluril-formaldehyde resins include, for example, CYMEL® resins (Dyno Cyanamid) and NIKALAC® resins (Sanwa Chemical). The resin having activated methylol and/or activated alkylated methylol groups is preferably a resole resin or a mixture of resole resins. Resole resins are well known to those skilled in the art. They are prepared by reaction of a phenol with an aldehyde under basic conditions using an excess of phenol. Commercially available resole resins include, for example, GP649D99 resole (Georgia Pacific) and BKS-5928 resole resin (Union Carbide). Useful secondary additional polymeric materials can also include copolymers that comprise from about 25 to about 75 mole % of recurring units derived from N-phenylmaleimide, from about 10 to about 50 mole % of recurring units derived from methacrylamide, and from about 5 to about 30 mole % of recurring units derived from methacrylic acid. These secondary additional copolymers are disclosed in U.S. Pat. No. 6,294,311 (Shimazu et al.) and U.S. Pat. No. 6,528,228 (Savariar-Hauck et al.).

Thus, the first polymeric binder can be a (meth)acrylic resin comprising carboxy groups, a maleated wood rosin, a styrene-maleic anhydride copolymer, a (meth)acrylamide polymer, a (meth)acrylonitrile polymer, a polymer derived from an N-substituted cyclic imide, a polymer having pendant cyclic urea groups, or polymers derived from an N-alkoxyalkyl methacrylamide. and that will not otherwise adversely affect the reaction.

In most embodiments, the inner layer further comprises an infrared radiation absorbing compound (“IR absorbing compounds”) that absorbs radiation at from about 600 to about 1400 and typically at from about 700 to about 1200 nm, with minimal absorption at from about 300 to about 600 nm. In most embodiments, the infrared radiation absorbing compound is present only in the inner layer.

Examples of suitable IR dyes include but are not limited to, azo dyes, squarylium dyes, triarylamine dyes, thioazolium dyes, indolium dyes, oxonol dyes, oxazolium dyes, cyanine dyes, merocyanine dyes, phthalocyanine dyes, indocyanine dyes, indotricarbocyanine dyes, hemicyanine dyes, streptocyanine dyes, oxatricarbocyanine dyes, thiocyanine dyes, thiatricarbocyanine dyes, merocyanine dyes, cryptocyanine dyes, naphthalocyanine dyes, polyaniline dyes, polypyrrole dyes, polythiophene dyes, chalcogenopyryloarylidene and bi(chalcogenopyrylo)-polymethine dyes, oxyindolizine dyes, pyrylium dyes, pyrazoline azo dyes, oxazine dyes, naphthoquinone dyes, anthraquinone dyes, quinoneimine dyes, methine dyes, arylmethine dyes, polymethine dyes, squaraine dyes, oxazole dyes, croconine dyes, porphyrin dyes, and any substituted or ionic form of the preceding dye classes. Suitable dyes are described for example, in U.S. Pat. No. 4,973,572 (DeBoer), U.S. Pat. No. 5,208,135 (Patel et al.), U.S. Pat. No. 5,244,771 (Jandrue Sr. et al.), and U.S. Pat. No. 5,401,618 (Chapman et al.), and EP 0 823 327A1 (Nagasaka et al.). WO 2004/101280 (Munnelly et al.).

Cyanine dyes having an anionic chromophore are also useful. For example, the cyanine dye may have a chromophore having two heterocyclic groups. In another embodiment, the cyanine dye may have at least two sulfonic acid groups, more particularly two sulfonic acid groups and two indolenine groups. Useful IR-sensitive cyanine dyes of this type are described for example in U.S Patent Application Publication 2005-0130059 (Tao).

In addition to low molecular weight IR-absorbing dyes, IR dye moieties bonded to polymers can be used as well. Moreover, IR dye cations can be used as well, that is, the cation is the IR absorbing portion of the dye salt that ionically interacts with a polymer comprising carboxy, sulfo, phospho, or phosphono groups in the side chains.

Near infrared absorbing cyanine dyes are also useful and are described for example in U.S. Pat. No. 6,309,792 (Hauck et al.), U.S. Pat. No. 6,264,920 (Achilefu et al.), U.S. Pat. No. 6,153,356 (Urano et al.), and U.S. Pat. No. 5,496,903 (Watanabe et al.). Suitable dyes may be formed using conventional methods and starting materials or obtained from various commercial sources including American Dye Source (Baie D'Urfe, Quebec, Canada) and FEW Chemicals (Germany). Other useful dyes for near infrared diode laser beams are described, for example, in U.S Pat. No. 4,973,572 (noted above).

Useful IR absorbing compounds include various pigments including carbon blacks such as carbon blacks that are surface-functionalized with solubilizing groups are well known in the art. Carbon blacks that are grafted to hydrophilic, nonionic polymers, such as FX-GE-003 (manufactured by Nippon Shokubai), or which are surface-functionalized with anionic groups, such as CAB-O-JET® 200 or CAB-O-JET® 300 (manufactured by the Cabot Corporation) are also useful. Other useful pigments include, but are not limited to, Heliogen Green, Nigrosine Base, iron (III) oxides, manganese oxide, Prussian Blue, and Paris Blue. The size of the pigment particles should not be more than the thickness of the imageable layer.

The infrared radiation absorbing compound can be present in the multi-layer imageable element in an amount of generally at least 0.5% and up to 30% and typically from about 3 to about 25%, based on the total dry weight of the element. The particular amount of a given compound to be used could be readily determined by one skilled in the art.

The inner layer can include other components such as surfactants, dispersing aids, humectants, biocides, viscosity builders, drying agents, defoamers, preservatives, antioxidants, and colorants.

The inner layer generally has a dry coating coverage of from about 0.5 to about 2.5 g/m² and typically from about I to about 2 g/m². The first polymeric binders described above generally comprise at least 50 weight % and typically from about 60 to about 90 weight % based on the total dry layer weight, and this amount can be varied depending upon what other polymers and chemical components are present. Any primary and secondary additional polymeric materials (such as a novolak, resole, or copolymers noted above) can be present in an amount of from about 5 to about 45 weight % based on the total dry weight of the inner layer.

The outer layer of the imageable element is disposed over the inner layer and in most embodiments there are no intermediate layers between the inner and outer layers. The outer layer comprises a second polymeric binder that is usually different than the first polymeric binder described above. These polymeric binders are generally soluble in alkaline developers (defined below) after thermal imaging. They can be poly(vinyl phenols) or derivatives thereof, or phenolic polymers. These polymeric binders are distinguishable from other polymeric binders that may be present in one or more layers of the imageable elements by the presence of carboxylic (carboxy), sulfonic (sulfo), phosphonic (phosphono), or phosphoric acid groups that are incorporated into the polymer molecule.

The resins useful as polymeric binders include but are not limited to, poly(hydroxystyrenes), novolak resins, resole resins, poly(vinyl acetals) having pendant phenolic groups, and mixtures of any of these resins (such as mixtures of one or more novolak resins and one or more resole resins). The novolak resins are particularly useful.

Generally, such resins have a number average molecular weight of at least 3,000 and up to 200,000, and typically from about 6,000 to about 100,000, as determined using conventional procedures. Most of these types of resins are commercially available or prepared using known reactants and procedures. For example, the novolak resins can be prepared by the condensation reaction of a phenol with an aldehyde in the presence of an acid catalyst. Typical novolak resins include but are not limited to, phenol-formaldehyde resins, cresol-formaldehyde resins, phenol-cresol-formaldehyde resins, p-t-butylphenol-formaldehyde resins, and pyrogallol-acetone resins, such as novolak resins prepared from reacting m-cresol or a m,p-cresol mixture with formaldehyde using conventional conditions. For example, some useful novolak resins include but are not limited to, xylenol-cresol resins, for example, SPN400, SPN420, SPN460, and VPN 1100 (that are available from AZ Electronics) and EP25D40G and EP25D50G that have higher molecular weights, such as at least 4,000.

Other useful resins include polyvinyl compounds having phenolic hydroxyl groups, include poly(hydroxystyrenes) and copolymers containing recurring units of a hydroxystyrene and polymers and copolymers containing recurring units of substituted hydroxystyrenes.

Also useful are branched poly(hydroxystyrenes) having multiple branched hydroxystyrene recurring units derived from 4-hydroxystyrene as described for example in U.S. Pat. No. 5,554,719 (Sounik) and U.S. Pat. No. 6,551,738 (Ohsawa et al.), and U.S. Published Patent Applications 2003/0050191 (Bhatt et al.) and 2005/0051053 (Wisnudel et al.), and in copending and commonly assigned U.S. patent application Ser. No. 11/474,020 (filed Jun. 23, 2006 by M. Levanon, J. Ray, K. Ray, L. Postel, and L. Korionoff) that is incorporated herein by reference. For example, such branched hydroxystyrene polymers comprise recurring units derived from a hydroxystyrene, such as from 4-hydroxystyrene, which recurring units are further substituted with repeating hydroxystyrene units (such as 4-hydroxystyrene units) positioned ortho to the hydroxy group. These branched polymers can have a weight average molecular weight (M_{w}) of from about 1,000 to about 30,000, preferably from about 1,000 to about 10,000, and more preferably from about 3,000 to about 7,000. In addition, they may have a polydispersity less than 2 and preferably from about 1.5 to about 1.9. The branched poly(hydroxystyrenes) can be homopolymers or copolymers with non-branched hydroxystyrene recurring units.

One group of useful polymeric binders are poly(vinyl phenol) and derivatives thereof. Such polymers are obtained generally by polymerization of vinyl phenol monomers, that is, substituted or unsubstituted vinyl phenols. Substituted vinyl phenol recurring units include those described below for the “a” recurring units in Structure (POLYMER). Some vinyl phenol copolymers are described in EP 1,669,803A (Barclay et al.).

Other useful polymeric binders are modified novolak or resole resins that are represented in the following Structure (POLYMER):

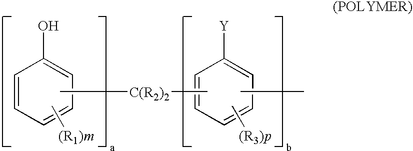

wherein

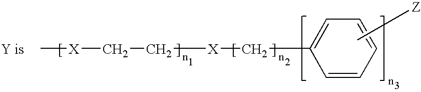

a is from about 90 to about 99 mol % (typically from about 92 to about 98 mol %), b is from about 1 to about 10 mol % (typically from about 2 to about 8 mol %), R₁ and R₃ are independently hydrogen or hydroxy, alkyl, or alkoxy groups, R₂ is hydrogen or an alkyl group, X is an alkylene, oxy, thio, —OC(═O)Ar—, —OC(═O)CH═CH—, or —OCO(CH₂)ₙ₄— group wherein Ar is an aryl group, m and p are independently 1 or 2, n₁ is 0 or an integer up to 5 (for example 0, 1, 2, or 3), n₂ is 0 or an integer up to 5 (for example, 0, 1, or 2), n₃ is 0 or 1 (typically 0), n₄ is a least 1 (for example, up to 8), and Z is —C(═O)OH, —S(═O)₂OH, —P(═O)(OH)₂, or —OP(═O)(OH)₂.

The alkyl and alkoxy groups present in the primary polymeric binders (for R¹, R², and R³) can be unsubstituted or substituted with one or more halo, nitro, or alkoxy groups, and can have 1 to 3 carbon atoms. Such groups can be linear, branched, or cyclic (that is, “alkyl” also include “cycloalkyl” for purposes of this invention).

When X is alkylene, it can have 1 to 4 carbon atoms and be further substituted similarly to the alkyl and alkoxy groups. In addition, the alkylene group can be a substituted or unsubstituted cycloalkylene group having at least 5 carbon atoms in the ring and chain. Ar is a substituted or unsubstituted, 6 or 10-membered carbocyclic aromatic group such as substituted or unsubstituted phenyl and naphthyl groups. Typically, Ar is an unsubstituted phenyl group.

In some embodiments, the polymeric binder comprises recurring units represented by Structure (I) wherein a is from about 92 to about 98 mol %, b is from about 2 to about 8 mol % and Z is —C(═O)OH, and is present at a dry coverage of from about 15 to 100 weight % based on the total dry weight of the layer.

Other polymeric binders that may be in the imageable layer include phenolic resins such as novolak and resole resins, and such resins can also include one or more pendant diazo, carboxylate ester, phosphate ester, sulfonate ester, sulfinate ester, or ether groups. The hydroxy groups of the phenolic resins can be converted to -T-Z groups in which T represents a polar group and Z represents a non-diazide functional group as described for example in U.S. Pat. No. 6,218,083 (McCullough et al.) and WO 99/001795 (McCullough et al.). The hydroxy groups can also be derivatized with diazo groups containing o-naphthoquinone diazide moieties as described for example in U.S. Pat. No. 5,705,308 (West et al.) and U.S. Pat. No. 5,705,322 (West et al.). Other useful secondary binder resins include acrylate copolymers as described for example in EP 737,896A (Ishizuka et al.), cellulose esters and poly(vinyl acetals) as described for example in U.S. Pat. No. 6,391,524 (Yates et al.), DE 10 239 505 (Timpe et al.), and WO 2004081662 (Memetea et al.).

Other useful polymeric binders are described, for example, in U.S. Pat. No. 7,163,770 (Saraiya et al.) and U.S. Pat. No. 7,160,653 (Huang et al.).

The one or more second polymeric binders are present in the outer layer at a dry coverage of from about 15 to 100 weight %, typically from about 70 to about 98 weight %, based on total dry weight of the outer layer.

The outer layer is usually substantially free of infrared radiation absorbing compounds, meaning that none of these compounds are purposely incorporated therein and insubstantial amounts diffuse into it from other layers.

Solubility-suppressing components are optionally incorporated into the imageable layer to act as dissolution inhibitors that function as solubility-suppressing components for the polymeric binders. Dissolution inhibitors typically have polar functional groups that are believed to act as acceptor sites for hydrogen bonding with various groups in the polymeric binders. The acceptor sites comprise atoms with high electron density, and can be selected from electronegative first row elements such as carbon, nitrogen, and oxygen. Dissolution inhibitors that are soluble in the alkaline developer are useful. Useful polar groups for dissolution inhibitors include but are not limited to, ether groups, amine groups, azo groups, nitro groups, ferrocenium groups, sulfoxide groups, sulfone groups, diazo groups, diazonium groups, keto groups, sulfonic acid ester groups, phosphate ester groups, triarylmethane groups, onium groups (such as sulfonium, iodonium, and phosphonium groups), groups in which a nitrogen atom is incorporated into a heterocyclic ring, and groups that contain a positively charged atom (such as quaternized ammonium group). Compounds that contain a positively-charged nitrogen atom useful as dissolution inhibitors include, for example, tetralkyl ammonium compounds and quaternized heterocyclic compounds such as quinolinium compounds, benzothiazolium compounds, pyridinium compounds, and imidazolium compounds. Further details and representative compounds useful as dissolution inhibitors are described for example in U.S. Pat. No. 6,294,311 (noted above). Useful dissolution inhibitors include triarylmethane dyes such as ethyl violet, crystal violet, malachite green, brilliant green, Victoria blue B, Victoria blue R, and Victoria pure blue BO, BASONYL® Violet 610 and D11 (PCAS, Longjumeau, France).

The outer layer generally also includes colorants. Useful colorants are described for example in U.S. Pat. No. 6,294,311 (noted above) including triarylmethane dyes such as ethyl violet, crystal violet, malachite green, brilliant green, Victoria blue B, Victoria blue R, and Victoria pure blue BO. These compounds can act as contrast dyes that distinguish the non-exposed regions from the exposed regions in the developed imageable element. The outer layer can optionally also include contrast dyes, printout dyes, coating surfactants, dispersing aids, humectants, biocides, viscosity builders, drying agents, defoamers, preservatives, and antioxidants.

The outer layer generally has a dry coating coverage of from about 0.2 to about 2 g/m² and typically from about 0.4 to about 1.5 g/m².

There may be a separate layer that is between and in contact with the inner and outer layers. This separate layer can act as a barrier to minimize migration of radiation absorbing compound(s) from the inner layer to the outer layer. This separate “barrier” layer generally comprises a third polymeric binder that is soluble in the alkaline developer. If this third polymeric binder is different from the first polymeric binder(s) in the inner layer, it is typically soluble in at least one organic solvent in which the inner layer first polymeric binders are insoluble. A useful third polymeric binder is a poly(vinyl alcohol).

Alternatively, there may be a separate layer between the inner and outer layers that contains the infrared radiation absorbing compound(s), which may also be present in the inner layer, or solely in the separate layer.

### Preparation of Imageable Elements

The multi-layer imageable element can be prepared by sequentially applying an inner layer formulation over the surface of the hydrophilic substrate (and any other hydrophilic layers provided thereon), and then applying an outer layer formulation over the inner layer using conventional coating or lamination methods. It is important to avoid intermixing of the inner and outer layer formulations.

For example, a multi-layer imageable element can be prepared with an inner layer comprising a first polymeric binder and a radiation absorbing compound, and an ink receptive outer layer comprising a second polymeric binder that is usually different than the first polymeric binder and is soluble in an alkaline developer upon exposure to imaging radiation.

The inner and outer layers can be applied by dispersing or dissolving the desired ingredients in a suitable coating solvent, and the resulting formulations are sequentially or simultaneously applied to the substrate using suitable equipment and procedures, such as spin coating, knife coating, gravure coating, die coating, slot coating, bar coating, wire rod coating, roller coating, or extrusion hopper coating. The formulations can also be applied by spraying onto a suitable support.

The selection of solvents used to coat both the inner and outer layers depends upon the nature of the first and second polymeric binders, other polymeric materials, and other components in the formulations. To prevent the inner and outer layer formulations from mixing or the inner layer from dissolving when the outer layer formulation is applied, the outer layer formulation should be coated from a solvent in which the first polymeric binder(s) of the inner layer are insoluble.

Generally, the inner layer formulation is coated out of a solvent mixture of methyl ethyl ketone (MEK), 1-methoxy-2-propyl acetate (PMA), γ-butyrolactone (BLO), and water, a mixture of MEK, BLO, water, and 1-methoxypropan-2-ol (also known as Dowanol® PM or PGME), a mixture of diethyl ketone (DEK), water, methyl lactate, and BLO, a mixture of DEK, water, and methyl lactate, or a mixture of methyl lactate, methanol, and dioxolane.

The outer layer formulation can be coated out of solvents or solvent mixtures that do not dissolve the inner layer. Typical solvents for this purpose include but are not limited to, butyl acetate, iso-butyl acetate, methyl iso-butyl ketone, DEK, 1-methoxy-2-propyl acetate (PMA), iso-propyl alcohol, PGME and mixtures thereof. Particularly useful is a mixture of DEK and PMA, or a mixture of DEK, PMA, and isopropyl alcohol.

Alternatively, the inner and outer layers may be applied by extrusion coating methods from melt mixtures of the respective layer formulations. Typically, such melt mixtures contain no volatile organic solvents.

Intermediate drying steps may be used between applications of the various layer formulations to remove solvent(s) before coating other formulations. Drying steps may also help in preventing the mixing of the various layers.

After drying the layers, the element can be further “conditioned” with a heat treatment at from about 40 to about 90° C. for at least 4 hours (for example, at least 20 hours) under conditions that inhibit the removal of moisture from the dried layers. For example, the heat treatment is carried out at from about 50 to about 70° C. for at least 24 hours. During the heat treatment, the imageable element is wrapped or encased in a water-impermeable sheet material to represent an effective barrier to moisture removal from the precursor, or the heat treatment of the imageable element is carried out in an environment in which relative humidity is controlled to at least 25%. In addition, the water-impermeable sheet material can be sealed around the edges of the imageable element, with the water-impermeable sheet material being a polymeric film or metal foil that is sealed around the edges of the imageable element.

In some embodiments, this heat treatment can be carried out with a stack comprising at least 100 of the same imageable elements, or when the imageable element is in the form of a coil or web. When conditioned in a stack, the individual imageable elements may be separated by suitable interleaving papers. Such papers are available from several commercial sources. The interleaving papers may be kept between the imageable elements after conditioning during packing, shipping, and use by the customer.

Representative methods for preparing multi-layer imageable elements of this invention are shown in Invention Examples below. Single layer imageable elements can be similarly prepared using the layer compositions described above.

Once the imageable elements are prepared with the desired layers, the micro-roughening process can be carried out as described above.

### Imaging and Development

The single- and multi-layer imageable elements can have any useful form including, but not limited to, printing plate precursors, printing cylinders, printing sleeves (solid or hollow cores) and printing tapes (including flexible printing webs). For example, the imageable members can be lithographic printing plate precursors useful for providing lithographic printing plates having hydrophilic substrates.

During use, the single- and multi-layer imageable elements are exposed to a suitable laser imaging using radiation such as UV, visible, or infrared radiation, depending upon the radiation absorbing compound present in the element, for example at a wavelength of from about 300 to about 1400 nm. In some embodiments, imaging can be carried out using an infrared laser at a wavelength of from about 600 to about 1500 nm and typically from about 700 to about 1200 nm. The lasers used to expose the imageable elements are usually diode lasers, because of the reliability and low maintenance of diode laser systems, but other lasers such as gas or solid-state lasers may also be used. The combination of power, intensity and exposure time for laser imaging would be readily apparent to one skilled in the art. Presently, high performance lasers or laser diodes used in commercially available imagesetters emit infrared radiation at a wavelength of from about 800 to about 1120 nm.

The imaging apparatus can function solely as a platesetter or it can be incorporated directly into a lithographic printing press. In the latter case, printing may commence immediately after imaging, thereby reducing press set-up time considerably. The imaging apparatus can be configured as a flatbed recorder or as a drum recorder, with the imageable member mounted to the interior or exterior cylindrical surface of the drum. Examples of useful imaging apparatus are available as models of Kodak Trendsetter imagesetters available from Eastman Kodak Company (Burnaby, British Columbia, Canada) that contain laser diodes that emit near infrared radiation at a wavelength of about 830 nm. Other suitable imaging sources include the Crescent 42T Platesetter that operates at a wavelength of 1064 nm and the Screen PlateRite 4300 series or 8600 series platesetter (available from Screen, Chicago, Ill.). Additional useful sources of radiation include direct imaging presses that can be used to image an element while it is attached to the printing plate cylinder. An example of a suitable direct imaging printing press includes the Heidelberg SM74-DI press (available from Heidelberg, Dayton, Ohio).

Imaging speeds may be in the range of from about 50 to about 1500 mJ/cm², and typically from about 75 to about 400 mJ/cm².

Direct digital imaging is generally used for imaging. The image signals are stored as a bitmap data file on a computer. Raster image processor (RIP) or other suitable means may be used to generate such files. The bitmaps are constructed to define the hue of the color as well as screen frequencies and angles.

Imaging of the imageable element produces an imaged element that comprises a latent image of imaged (exposed) and non-imaged (non-exposed) regions. Developing the imaged element with a suitable developer removes predominantly only the exposed regions of the outermost layer and the underlying portions of underlayers (such as an inner layer), and reveals the hydrophilic surface of the substrate. Thus, the imageable elements are “positive-working” (for example, positive-working lithographic printing plate precursors). The exposed (or imaged) regions of the hydrophilic surface repel ink while the non-exposed (or non-imaged) regions accept ink.

Development is carried out for a time sufficient off-press to remove the imaged (exposed) regions of the imaged element, but not long enough to remove the non-exposed regions. Thus, the imaged (exposed) regions of the imageable layer are described as being “soluble” or “removable” in the alkaline developer because they are removed, dissolved, or dispersed within the alkaline developer more readily than the non-imaged (non-exposed) regions. Thus, the term “soluble” also means “dispersible”.

Aqueous alkaline developers generally have a pH of from about 8 to about 14 and more typically of at least 12, or of at least 13. Useful alkaline aqueous developers include 3000 Developer, 9000 Developer, GoldStar™ Developer, Goldstar™ Plus Developer, GoldStar™ Premium, GREENSTAR Developer, ThermalPro Developer, PROTHERM Developer, MX1813 Developer, and MX1710 Developer (all available from Eastman Kodak Company), as well as Fuji HDP7 Developer (Fuji Photo) and Energy CTP Developer (Agfa). These compositions generally include surfactants, chelating agents (such as salts of ethylenediaminetetraacetic acid), and alkaline components (such as inorganic metasilicates, organic metasilicates, hydroxides, and bicarbonates).

Such alkaline developers can also include one or more “coating-attack suppressing agents” that are developer-soluble compounds that suppress developer attack of the outer layer. “Developer-soluble” means that enough of the agent(s) will dissolve in the developer to suppress attack by the developer. Mixtures of these compounds can be used. Typically, the coating-attack suppressing agents are developer-soluble polyethoxylated, polypropoxylated, or polybutoxylated compounds that include recurring —(CH₂—CHRₐ—O—)— units in which Rₐ is hydrogen or a methyl or ethyl group. Each agent can have the same or different recurring units (in a random or block fashion). Representative compounds of this type include but are not limited to, polyglycols and polycondensation products having the noted recurring units. Examples of such compounds and representative sources, tradenames, or methods of preparing are described for example in U.S. Pat. No. 6,649,324 (Fiebag et al.) that is incorporated herein by reference.

Organic solvent-containing alkaline developers may also be useful. These developers generally have a lower pH (for example, below 12) and are generally single-phase solutions of one or more organic solvents that are miscible with water, such as 2-ethylethanol and 2-butoxyethanol. Representative solvent-containing alkaline developers include ND-1 Developer, 955 Developer, 956 Developer, 989 Developer, and 980 Developer (all available from Eastman Kodak Company), HDN-1 Developer (available from Fuji), and EN 232 Developer (available from Agfa).

Generally, the alkaline developer is applied to the imaged element by rubbing or wiping the outer layer with an applicator containing the developer. Alternatively, the imaged element can be brushed with the developer or the developer may be applied by spraying the outer layer with sufficient force to remove the exposed regions. The imaged element can be immersed in the developer. In all instances, a developed image is produced, particularly in a lithographic printing plate having a hydrophilic aluminum-containing substrate.

Following development, the imaged element can be rinsed with water and dried in a suitable fashion. The dried element can also be treated with a conventional gumming solution (preferably gum arabic).

A postbake operation can be carried out, with or without a blanket or floodwise exposure to UV or visible radiation. The imaged and developed element can be baked in a postbake operation to increase run length of the resulting printing plate. Baking can be carried out, at from about 220° C. to about 240° C. for from about 7 to about 10 minutes, or at about 120° C. for 30 minutes. Alternatively, a blanket UV or visible radiation exposure can be carried out, without a postbake operation.

A lithographic ink and fountain solution can be applied to the printing surface of the imaged element for printing. The non-exposed (non-removed) regions of the outermost layer take up ink and the hydrophilic surface of the substrate revealed by the imaging and development process takes up the fountain solution. The ink is then transferred to a suitable receiving material (such as cloth, paper, metal, glass, or plastic) to provide a desired impression of the image thereon. If desired, an intermediate “blanket” roller can be used to transfer the ink from the imaged member to the receiving material. The imaged members can be cleaned between impressions, if desired, using conventional cleaning means and chemicals.

The following examples are presented to illustrate the practice of this invention but are not intended to be limiting in any manner.

### EXAMPLES

### Materials and Methods:

Byk® 307 is a polyethoxylated dimethylpolysiloxane copolymer that is available from Byk Chemie (Wallingford, Conn.) in a 25 wt. % xylene/-methoxypropyl acetate solution.

BLO represents y-butyrolactone.

Copolymer A represents a copolymer having recurring units derived from N-phenylmaleimide, methacrylamide, and methacrylic acid (45:35:20 mol %) using conventional conditions and procedures.

DEK represents diethyl ketone.

Dowanol® PM is propylene glycol methyl ether that was obtained from Dow Chemical (Midland, Mich.). It is also known as PGME.

Ethyl violet is assigned C.I. 42600 (CAS 2390-59-2, λₘₐₓ=596 nm) and has the formula of p-(CH₃CH₂)₂NC₆H₄)₃C⁺Cl⁻.

GP649D99 is a resole resin that was obtained from Georgia-Pacific (Atlanta, Ga.).

IR Dye A (Trump) is represented by the following structure and can be obtained from Eastman Kodak Company:

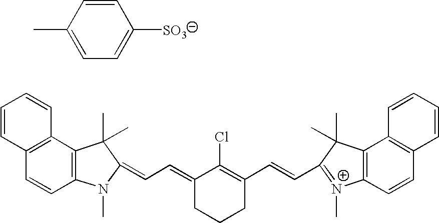

N13 is an m-cresol novolak that is available from Eastman Kodak Company (Rochester, N.Y.).

PD494 and PD 140A are m/p-cresol novolaks that were obtained from Borden Chemicals (Louisville, Ky.).

PMA represents 1-methoxy-2-propyl acetate. It is also known as Dowanol® PMA.

RAR 62 has the following polymer structure:

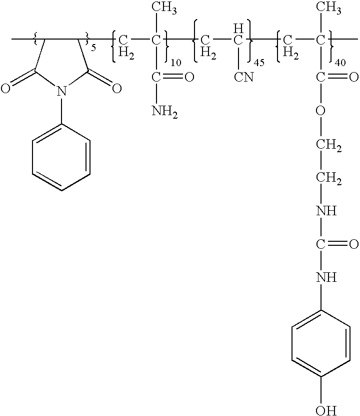

Substrate A is a 0.3 mm gauge aluminum sheet that had been electrograined, anodized, and treated with poly(vinyl phosphonic acid).

TN13 is a 15 mole % tosylated N13 that is available from Eastman Kodak Company.

T183-5 Developer is available from Eastman Kodak Company (Norwalk, Conn.).

GoldStar™ Premium Developer is an aqueous alkaline developer that is available from Eastman Kodak Company (Norwalk, Conn.).

Substrate A is a 0.3 mm gauge aluminum sheet that had been electrograined, anodized, and subjected to treatment with poly(vinyl phosphonic acid).

### Invention Examples 1-5 and Comparative Examples 1-2

A positive-working printing plate precursor (imageable element) was prepared as follows:

### Bottom (Inner) Layer 1:

A coating formulation was prepared by dissolving 5.80 of Copolymer A, 1.5 g of RAR 62, 4.16 g of GP649D99, 1.50 g of IR Dye A, and 0.05 g of Byk® 307 in 130 g of a solvent mixture comprising MEK (45 wt. %), PMA (35 wt. %), BLO (10 wt. %), and water (10 wt. %). The formulation was coated onto Substrate A and dried 135° C. for 45 seconds to provide a coating weight of approximately 1.5 g/m².

### Bottom (Inner) Layer 2:

A coating formulation was prepared by dissolving Copolymer A (5.0 g) and IR Dye A (0.7 g) in 90 ml of a solvent mixture comprising MEK (45 wt. %), PMA (35 wt. %), BLO (10 wt. %), and water (10 wt. %). It was coated onto Substrate A and dried at 135° C. for 45 seconds to provide a dry coating weight of about 1.35 g/m².

### Top (Outer) Layer 1:

A coating formulation was prepared by dissolving 2.38 g of TN13, 0.032 g of Ethyl Violet, and 0.030 g of Byk® 307 in 40 g of a solvent mixture of DEK and PMA (92:8 wt. ratio). The formulation was coated onto Bottom Layer 1 described above and dried at 135° C. for 45 seconds to give a top (outer) layer coating weight of approximately 0.65 g/m².

### Top (Outer) Layer 2:

A coating formulation was made like the Top (Outer) Layer 1 formulation by substituting TN13 with PD494.

Spray solutions were prepared by dissolving certain resins in specific solvents as shown below in TABLE I at the noted concentrations. The spray solutions were applied on to the multi-layer imageable elements defined in TABLE II below. The spray solutions were applied by holding the imageable element vertically and using a fine jet of pressurized gas to disperse the spray solution as a fine spray such that the sprayed particles are almost dry when reach the element outer surface.

TABLE I

| Spray | Dissolved | | Resin |
|---|---|---|---|
| Solution | Resin | Solvent | Concentration |
| Spray 1 | N13 | Isobutylacetate | 12 wt. % |
| Spray 2 | PD140 | Isobutylacetate | 10 wt. % |
| Spray 3 | TN13 | Isobutylacetate | 12 wt. % |

The following evaluations were made with the imageable elements:

Clear Point: Each imageable element was imagewise exposed at 360 rpm from 4 W to 10 W with a Kodak Quantum II 800 in steps of 1 Watt. The plate was developed with the respective developers at 23° C. in a Mercury processor at 1000 mm/min. and the clear point as found as shown in TABLE II. The cleanliness of the non-imaged areas in the resulting printing plates was inspected both in the solid non-image areas and in a fine 2×2 pixel screen using a microscope at 100× magnification. Any voids in the imaged areas were also evaluated by inspecting the sensitive 2×2 screen for white spots.

Scratch sensitivity: Scratch sensitivity was assessed by placing cylindrical metal weights of either 600 g and 1500 g on a smooth metal disc onto the top of the imageable element covered with an interleaf paper. The interleaf paper was then pulled at a constant speed and subsequently the imageable elements were imaged as described above and processed in the respective developers at 1000 mm/min. The resulting printing plates are assessed for scratches (at each weight value) and given a relative evaluation using a scale of 1 to 10 where 10 indicates the highest level of scratches and 1 indicates no scratches.

TABLE II

| | Bottom | Top | | | | | 100% Non- | Non-imaged in | Imaged areas (2 × 2 | Clear |
|---|---|---|---|---|---|---|---|---|---|---|
| | layer | layer | Spray | Developer | 600 g | 1500 g | imaged | screen (2 × 2 pixels) | pixels) | Point |
| Comparative | 1 | 1 | None | GoldStar ™ | 3 | 8 | Clean | No undeveloped spots | Good resolution; no | 11 W |
| Example 1 | | | | Premium | | | | | voids in the image | |
| Invention | 1 | 1 | Spray 1 | GoldStar ™ | 1 | 5 | Clean | No undeveloped spots | Good resolution; no | 11 W |
| Example 1 | | | | Premium | | | | | voids in the image | |
| Invention | 1 | 1 | Spray 3 | GoldStar ™ | 2 | 4 | Coating | No spots of | Good resolution; no | 11 W |
| Example 2 | | | | Premium | | | | undeveloped coating | voids in the image | |
| Invention | 1 | 1 | Spray 2 | GoldStar ™ | 2 | 5 | Clean | No spots of | Good resolution; no | 11 W |
| Example 3 | | | | Premium | | | | undeveloped coating | voids in the image | |
| Comparative | 1 | 2 | None | T183-5 | 3 | 8 | Clean | No spots of | Good resolution; no | 7 W |
| Example 2 | | | | | | | | undeveloped coating | voids in the image | |
| Invention | 1 | 2 | Spray 1 | T183-5 | 3 | 6 | Clean | No spots of | Good resolution; no | 7 W |
| Example 4 | | | | | | | | undeveloped coating | voids in the image | |
| Invention | 1 | 2 | Spray 2 | T183-5 | 3 | 6 | Clean | No spots of | Good resolution; no | 7 W |
| Example 5 | | | | | | | | undeveloped coating | voids in the image | |

The results shown in TABLE II indicate that abrasion resistance of the outer surface of the imageable element is improved through the application of sprayed particles without any loss in image quality or element sensitivity. Any damage to the outer surface of the top (Outer) layer causes image surface defects or holes in the imaged areas that pose a major problem in manufacturing, packaging, and transport. These defects were evident in the Comparative Examples 1 and 2. The improved scratch sensitivity provided by this invention offers a solution to this problem.

The invention has been described in detail with particular reference to certain preferred embodiments thereof, but it will be understood that variations and modifications can be effected within the spirit and scope of the invention.

1. A method of micro-roughening a computer-to-plate, IR laser-imageable multi-layer, positive-working imageable element comprising inner and outer layers disposed on a hydrophilic substrate, and further comprising an infrared radiation absorbing compound, said method comprising:
spraying a solution consisting essentially of one or more dissolved organic resins in a solvent onto the outer layer of said computer-to-plate, IR laser-imageable multi-layer, positive-working imageable element, said one or more organic resins being soluble or dispersible in an aqueous alkaline solution and being present in said solution in an amount of at least 3 weight %, said sprayed solution being applied in a manner to deposit at least 10 mg/m² and no more than 100 mg/m² of said one or more dissolved organic resins onto said outer layer in the form of dots in a random pattern, and
drying said sprayed dots in a random non-coated pattern on said outer layer.

2. A method of preparing a computer-to-plate, IR laser-imageable multi-layer, positive-working imageable element comprising:
A) providing a computer-to-plate, IR laser-imageable multi-layer, positive-working imageable element comprising a substrate having thereon inner and outer layers and an infrared radiation absorbing compound,
B) spraying a solution consisting essentially of one or more dissolved organic resins in a solvent onto said outer layer of said element, said one or more organic resins being soluble or dispersible in an aqueous alkaline solution and being present in said solution in an amount of at least 3 weight %, said sprayed solution being applied in a manner to deposit at least 10 mg/m² and no more than 100 mg/m² of said one or more dissolved organic resins onto said outer layer in the form of dots in a random pattern, and
C) drying said random dots on said outer layer to provide a random non-coated pattern of dried dots of said one or more organic resins on said outer layer.

3. The method of claim 2 wherein said one or more dissolved organic resins comprises a novolak, resole, polyhydroxystyrene, (meth)acrylic acid copolymer, poly(vinyl acetal), cellulose ester derivative, cyclic anhydride copolymer, polyurethane, or polymeric sulfonamide derivative.

4. The method of claim 2 wherein said one or more dissolved organic resins includes one or more novolak resins.

5. The method of claim 2 wherein said one or more dissolved organic resins are present in said sprayed solution in an amount of from about 3 to about 20 weight %.

6. The method of claim 2 wherein said sprayed solution is not sensitive to infrared radiation.

7. The method of claim 6 wherein said sprayed solution further comprises a surfactant.

8. (canceled)

9. The method of claim 2 wherein said one or more organic resins are soluble in an alkaline developer.

10. (canceled)

11. The method of claim 2 wherein said sprayed solution is applied in a manner to deposit from about 20 to about 50 mg/m² of said one or more organic resins onto said outer layer as said dots.

12. The method of claim 2 wherein said sprayed solution is applied by high pressure nozzle spraying or by electrostatic spraying.

13-17. (canceled)

18. A method of preparing a computer-to-plate, IR laser-imageable multi-layer, positive-working, infrared radiation-sensitive imageable element comprising:
A) providing a computer-to-plate, IR laser-imageable multi-layer, positive-working infrared radiation-sensitive imageable element comprising a substrate having thereon inner and outer layers, and further comprising an infrared radiation absorbing compound only in said inner layer,
B) spraying a solution consisting essentially of one or more dissolved organic resins in a solvent onto said outer layer of said element, said one or more organic resins being soluble or dispersible in an aqueous alkaline solution and being present in said solution in an amount of at least 3 weight %, said sprayed solution being applied in a manner to deposit at least 10 mg/m² and no more than 100 mg/m² of said one or more dissolved organic resins onto said outer layer in the form of dots in a random pattern, and
C) drying said random dots on said outer layer to provide a random, non-coated pattern of dried dots of said one or more organic resins on said outer layer.

19. (canceled)

20. The method of claim 18 wherein said infrared radiation absorbing compound is an infrared radiation dye.
